(19) United States
(12) Patent Application Publication
(10) Pub. No.: US 2013/0248827 A1
(43) Pub. Date: Sep. 26, 2013

(54) ORGANIC ELECTROLUMINESCENCE DISPLAY DEVICE

(71) Applicant: CANON KABUSHIKI KAISHA, Tokyo (JP)

(72) Inventors: Takeshi Togano, Suntou-gun (JP); Osamu Yoshitake, Kawasaki-shi (JP)

(73) Assignee: CANON KABUSHIKI KAISHA, Tokyo (JP)

(21) Appl. No.: 13/792,888

(22) Filed: Mar. 11, 2013

(30) Foreign Application Priority Data
Mar. 26, 2012 (JP) 2012-069385
Apr. 17, 2012 (JP) 2012-093478

(51) Int. Cl. H01L 51/52; H01L 51/50

(52) U.S. Cl. CPC H01L 51/5253; H01L 51/5012; H01L 51/524
USPC 257/40

(57) ABSTRACT

Provided is an organic electroluminescence display device which makes use of the hygroscopic ability of a water-absorbing silicon-containing polymer such as polysilazane and has highly reliable display performance, the organic electroluminescence display device including: a substrate; an organic electroluminescence element formed on the substrate; a hygroscopic layer for covering the organic electroluminescence element; a gas releasing member (gas releasing layer) provided in contact with the hygroscopic layer; and a sealing member (sealing substrate) provided over the hygroscopic layer in which the hygroscopic layer is formed of a hygroscopic silicon-containing polymer.

### BACKGROUND OF THE INVENTION

1. Field of the Invention

The present invention relates to an organic electroluminescence display device.

2. Description of the Related Art

An organic electroluminescence (EL) display device is a display device which includes multiple organic light emitting elements each including an anode, a cathode, and an organic compound layer provided between the cathode and the anode. The organic light emitting element is an electronic element in which, by applying electric current between the cathode and the anode, the organic compound layer therebetween emits light. An organic light emitting element included in an organic EL display device is of a self-emission type, and thus has the features of high visibility and being able to come down in thickness and weight compared with a liquid crystal display device. Therefore, an organic EL display device is in particular actively applied and developed for mobile uses, and has been put into practical use as a display device for a cellular phone or the like.

However, in an organic EL display device, a very small amount of moisture, oxygen, or the like alters the quality of an organic light emitting material which is a constituent material, or causes separation or the like between an emission layer and an electrode. There is a problem that this results in degradation of display performance such as reduction in light emitting efficiency or increase in non-light emitting region (dark spots).

As a specific measure against such a problem, Japanese Patent Application Laid-Open No. 2009-259788 discloses a sealing method in which a moisture resistant portion having an inner protective film, a polysilazane film, and a protective film laminated therein in this order is provided on an organic EL element. In this case, as the inner protective film and the protective film, films each formed of an inorganic material and having a low moisture permeability are used. According to this method, the polysilazane film inhibits infiltration of moisture from the outside as much as possible, and thus, the moisture resistance can be enhanced.

By the way, polysilazane has a repeated structural unit represented by the following general formula (A).

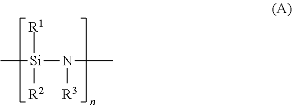

In Formula (A), each of R¹ to R³ denotes a hydrogen atom, an alkyl group, a cycloalkyl group, an aryl group, an alkylsilyl group, an alkylamino group, an alkoxy group, or a metal atom, and at least one of R¹ to R³ is a hydrogen atom.

In Formula (A), for example, polysilazane in which all of R¹ to R³ are hydrogen atoms absorbs moisture in the air to be converted into silica (SiO₂) which is excellent in moisture resistance as expressed by the following reaction formula.

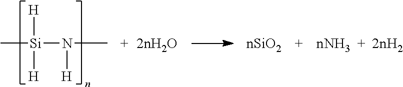

Therefore, polysilazane not only functions as a hygroscopic material which absorbs moisture in the air but also functions as a moisture resistant material when moisture in the air is absorbed therein. Therefore, it can be said that polysilazane is a useful material in an organic EL display device in which a very small amount of moisture, oxygen, or the like results in degradation of display performance such as reduction in light emitting efficiency or increase in dark spots.

However, as expressed by the above-mentioned reaction formula, when polysilazane reacts with water, hydrogen gas and ammonia gas are produced as by-products of the reaction, and thus, if polysilazane is hermetically sealed with a gas-impermeable film, problems arise such as evolution of air bubbles and separation at the interface.

### SUMMARY OF THE INVENTION

The present invention has been made to solve the above-mentioned problems, and has an object to provide an organic EL display device which makes use of the hygroscopic ability of a water-absorbing silicon-containing polymer such as polysilazane and has highly reliable display performance.

According to an exemplary embodiment of the present invention, there is provided an organic electroluminescence display device including:

a substrate;

an organic electroluminescence element formed on the substrate;

a hygroscopic layer for covering the organic electroluminescence element;

a gas releasing member provided in contact with the hygroscopic layer; and

a sealing member provided over the hygroscopic layer,

in which the hygroscopic layer includes a hygroscopic silicon-containing polymer.

According to the present invention, the organic EL display device can be provided which makes use of the hygroscopic ability of the water-absorbing silicon-containing polymer such as polysilazane and has highly reliable display performance.

Further features of the present invention will become apparent from the following description of exemplary embodiments with reference to the attached drawings.

### BRIEF DESCRIPTION OF THE DRAWINGS

FIG. 1 is a schematic cross-sectional view illustrating an organic EL display device according to a first embodiment of the present invention.

FIG. 2 is a schematic cross-sectional view illustrating an organic EL display device according to a second embodiment of the present invention.

FIG. 3 is a schematic cross-sectional view illustrating an organic EL display device according to a third embodiment of the present invention.

FIG. 4 is a schematic cross-sectional view illustrating an organic EL display device according to a fourth embodiment of the present invention.

FIG. 5 is a schematic cross-sectional view illustrating an organic EL display device according to a fifth embodiment of the present invention.

### DESCRIPTION OF THE EMBODIMENTS

An organic EL display device according to the present invention includes a substrate, an organic EL element formed on the substrate, a hygroscopic layer for covering the organic EL element, a gas releasing member provided in contact with the hygroscopic layer, and a sealing member provided over the hygroscopic layer. Further, in the organic EL display device according to the present invention, the hygroscopic layer contains a hygroscopic silicon-containing polymer. In this case, it is preferred that the hygroscopic silicon-containing polymer be polysilazane. Note that, according to the present invention, the gas releasing member may be formed of a single layer or may be formed of multiple layers. When the gas releasing member is formed of multiple layers, the gas releasing member is a laminate including, for example, a gas permeable layer and a gas releasing layer. Further, the sealing member which forms the organic EL display device is, specifically, a sealing substrate, or a sealing film formed of a material having a low moisture permeability.

Organic EL display devices according to the present invention are described in the following with reference to the attached drawings. Note that, a well-known or publicly known technology in the art may be applied to portions which are not specifically illustrated or described in the following description. Further, embodiments described in the following are only exemplary embodiments according to the present invention, and the present invention is not limited thereto.

### First Embodiment

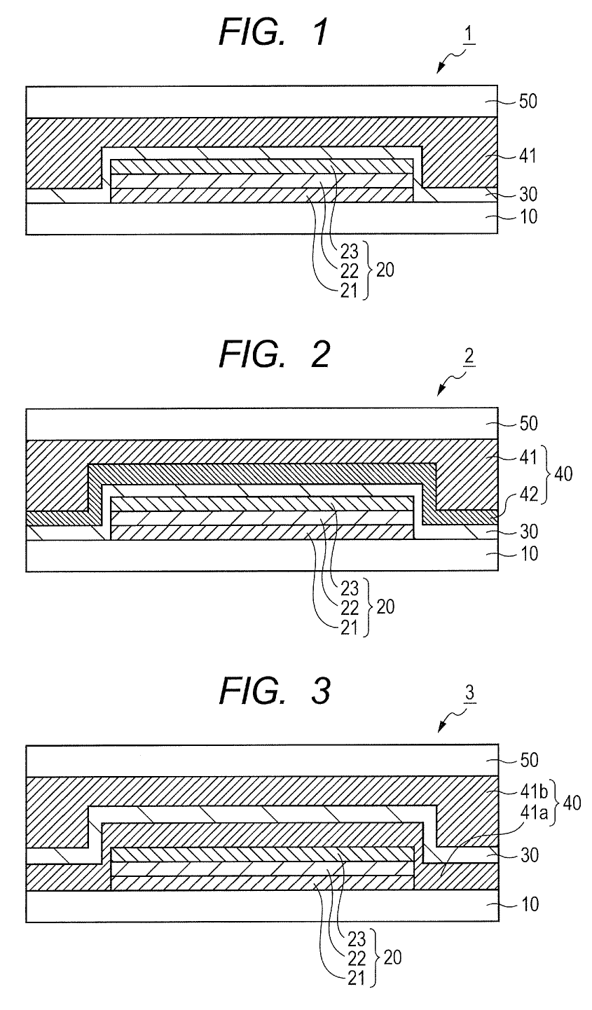

FIG. 1 is a schematic cross-sectional view illustrating an organic EL display device according to a first embodiment of the present invention.

An organic EL display device 1 illustrated in FIG. 1 includes an organic EL element 20 which is formed by laminating on a substrate 10 a first electrode 21, an organic compound layer 22, and a second electrode 23 in this order. In the organic EL display device 1 illustrated in FIG. 1, the organic EL element 20 is covered with a hygroscopic layer 30, and the hygroscopic layer 30 is covered with a gas releasing layer 41 as a gas releasing member. A sealing substrate 50 is provided on the gas releasing layer 41 so as to cover the gas releasing layer 41. By the way, in the organic EL display device 1 illustrated in FIG. 1, one organic EL element 20 is provided on the substrate 10, but the present invention is not limited to the embodiment illustrated in FIG. 1, and multiple organic EL elements 20 may be provided on the substrate 10.

Examples of the substrate 10 which is a constituent material of the organic EL display device 1 include a glass substrate, an insulating substrate formed of a synthetic resin or the like, a conductive substrate having an insulating layer of silicon oxide, or silicon nitride formed on the surface thereof, and a semiconductor substrate. Further, the substrate 10 itself may be transparent or opaque.

The first electrode 21 is an electrode provided on the substrate 10, and is a conductive thin film which is also called a lower electrode. The first electrode 21 may be a transparent electrode or a reflective electrode. When the first electrode 21 is a transparent electrode, examples of a constituent material thereof include a transparent conductive material such as ITO and In₂O₃. On the other hand, when the first electrode 21 is a reflective electrode, examples of a constituent material thereof include a single-component metal such as Au, Ag, Al, Pt, Cr, Pd, Se, or Ir, an alloy which is a combination of multiple kinds of these single-component metals, and a metal compound such as copper iodide. It is preferred that the thickness of the first electrode 21 be 0.1 μm to 1 μm.

The organic compound layer 22 provided on the first electrode 21 is a layer or a laminate formed of multiple layers including at least an emission layer. When the organic compound layer 22 is formed of multiple layers, the layers forming the organic compound layer 22 can be appropriately selected taking into consideration the emission function of the organic EL element. Specific examples of layers other than the emission layer, which form the organic compound layer 22, include a hole injection layer, a hole transport layer, an electron transport layer, and an electron injection layer. Further, as a constituent material of the organic compound layer 22, a publicly known compound may be used. Further, the organic compound layer 22 can be formed by a publicly known thin film forming method such as vacuum deposition or ink jet.

The second electrode 23 formed on the organic compound layer 22 is a conductive thin film which is also called an upper electrode. The second electrode 23 may be a transparent electrode or a reflective electrode, and is appropriately selected depending on the property of the first electrode 21. Further, a constituent material of the second electrode 23 may be a material similar to that of the above-mentioned first electrode 21.

The hygroscopic layer 30 is formed on the organic EL element 20 so as to cover the organic EL element 20. The hygroscopic layer 30 is a layer formed of a water-absorbing silicon-containing polymer. The silicon-containing polymer as a constituent material of the hygroscopic layer 30 is not specifically limited insofar as the polymer contains silicon and can absorb moisture in the air, but it is preferred that the silicon-containing polymer be polysilazane having a repeated structure represented by the following Formula (A).

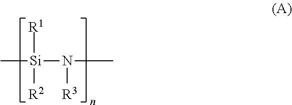

In Formula (A), each of R¹ to R³ denotes a hydrogen atom, an alkyl group, a cycloalkyl group, an aryl group, an alkylsilyl group, an alkylamino group, an alkoxy group, or a metal atom, and at least one of R¹ to R³ is a hydrogen atom.

For example, when a polymer represented by Formula (A) in which R¹ is a lower alkyl group and R² and R³ are hydrogen atoms is a constituent material of the hygroscopic layer 30, the hygroscopic layer 30 is converted into a silica film including a lower alkyl group in the structure when the hygroscopic layer 30 reacts with water. Therefore, in such a case, although the denseness of the film is inferior to that of an inorganic silica film, the hygroscopic layer 30 can be formed with a large thickness.

On the other hand, polysilazane represented by Formula (A) in which R¹, R², and R³ are all hydrogen atoms is also called perhydropolysilazane. Perhydropolysilazane reacts with water as expressed by the following reaction formula to produce a dense silica (SiO₂) film, which functions as a moisture resistant layer after the reaction. Therefore, perhydropolysilazane is particularly suitable when used as the hygroscopic layer.

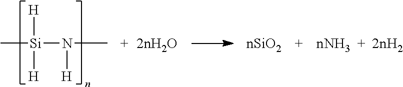

When the hygroscopic layer 30 is formed, an application method such as spin coating can be used. For example, the hygroscopic layer 30 can be formed by dropping and applying a solution prepared by dissolving a water-absorbing silicon-containing polymer in an organic solvent on the organic EL element 20 and the substrate 10. The thickness of the formed hygroscopic layer 30 is appropriately designed taking into consideration the amount of moisture which infiltrates from the external environment and the water-absorbing ability of the silicon-containing polymer used as the hygroscopic layer, and is not specifically limited. In this case, from the viewpoint of uniformly forming the hygroscopic layer 30 on the organic EL element 20, it is preferred that the thickness of the hygroscopic layer 30 be 10 nm or more. Further, when perhydropolysilazane is used as the silicon-containing polymer, from the viewpoint of inhibiting a crack which may develop in the formed hygroscopic layer 30, it is preferred that the thickness of the hygroscopic layer 30 be 2,000 nm or less.

The hygroscopic layer 30 is formed by dropping and applying a solution prepared by dissolving a silicon-containing polymer in an organic solvent, and thus, when the second electrode formed therebelow has a defect such as a pin hole, the organic solvent may infiltrate therefrom to damage the organic EL element 20. Therefore, although not illustrated in the organic EL display device 1 in FIG. 1, a protective layer for preventing damage to the organic EL element 20 may be provided before the hygroscopic layer 30 is formed. It is preferred that the material of the protective layer be resistant to an organic solvent, and an inorganic insulating layer formed of SiN, SiON, SiO₂, or the like is suitable. It is preferred that the thickness of the protective layer be 10 nm or more.

The gas releasing layer 41 formed on the hygroscopic layer 30 is a layer which is provided so as to be in contact with the hygroscopic layer 30 and so that part thereof is exposed to the outside. The gas releasing layer 41 functions as a layer for releasing gas evolved from the hygroscopic layer 30 to the outside.

The gas releasing layer 41 includes a resin layer formed of a resin material. Examples of the resin material as a constituent material of the gas releasing layer 41 include a UV-curable resin, a thermosetting resin, a thermoplastic resin, and the like.

These resin layers are formed by, for example, forming a film of the above-mentioned resin material by a slit coater, screen printing, or the like. Further, the above-mentioned resin material may be processed into a sheet to be provided on the hygroscopic layer 30.

Note that, if the resin material used as the gas releasing member contains a large amount of moisture, the resin material itself consumes the ability of the hygroscopic layer, and thus, the water content is preferably 5,000 ppm or less, and more preferably 1,000 ppm or less. Further, in the case where the gas releasing member is formed by reacting a precursor of a resin with ultraviolet radiation, heat, or the like to be cured, and if water is produced as a reaction product, this also consumes the ability of the hygroscopic layer. Therefore, it is preferred to use a resin material which does not produce water as a product in the formation.

In the organic EL display device 1 illustrated in FIG. 1, sealing treatment is carried out by bonding together the substrate 10 and the sealing substrate 50.

Examples of the sealing substrate 50 include a glass substrate, an insulating substrate formed of a synthetic resin or the like, and a conductive substrate having an insulating layer of silicon oxide, silicon nitride, or the like formed on the surface thereof. Further, the sealing substrate 50 may be transparent or opaque, but, when light is emitted from the sealing substrate 50, a transparent substrate is used.

Examples of the specific method of carrying out the sealing treatment include a method of providing an adherent member (adhesive layer) on the gas releasing layer 41 to bond the substrate 10 and the sealing substrate 50 together. The material of the adhesive layer is not specifically limited, but is preferably a resin material, and more preferably, similarly to the gas releasing layer 41, a UV-curable resin, a thermosetting resin, or a thermoplastic resin. Note that, the adhesive layer is, similarly to the gas releasing layer 41, formed by forming a film of a resin material by a slit coater, screen printing, or the like. Further, the adhesive layer may be formed by processing the above-mentioned resin material into a sheet to be provided on the gas releasing layer 41.

On the other hand, when a constituent material of the gas releasing layer 41 is an adherent material, the gas releasing layer 41 itself can be used as an adhesive layer to be bonded to the sealing substrate 50.

By the way, as represented by Formula 4, when polysilazane reacts with reaction water to change its structure into a dense silica-based inorganic structure, contraction in volume occurs. For example, in the case of using polysilazane added with an amine-based catalyst which can be converted into silica at a low temperature, a film obtained by applying and then baking the material at 100° C. reacts with water to increase its density from 1.3 g/cm³ to 1.6 g/cm³. It is known that, in this case, the volume of the film contracts by about 10%.

By providing the gas releasing layer 41 formed of a resin material so as to be in contact with the hygroscopic layer 30, the gas releasing layer 41 also functions as a stress alleviating layer for alleviating transfer of stress caused by the contraction in volume of the hygroscopic layer 30 to the sealing member. As a result, separation at the interface between the hygroscopic layer and the gas releasing layer 41 and a defect in the sealing layer can be inhibited as well.

### Second Embodiment

FIG. 2 is a schematic cross-sectional view illustrating an organic EL display device according to a second embodiment of the present invention. In the following, the second embodiment according to the present invention is described with reference to FIG. 2. Note that, in the following description, points different from those in the first embodiment are mainly described.

An organic EL display device 2 illustrated in FIG. 2 is different from the organic EL display device in the first embodiment in that a gas releasing member 40 for releasing gas evolved from the hygroscopic layer 30 is a laminate formed by laminating a gas permeable layer 42 and the gas releasing layer 41 in this order.

Polysilazane has reactivity also with a compound other than water insofar as the compound has a hydroxyl group (—OH). Therefore, if a constituent material of the gas releasing layer 41 formed on the hygroscopic layer 30 is a compound having a hydroxyl group, or if dehydration treatment of a constituent material of the gas releasing layer 41 is insufficient, when the gas releasing layer 41 is formed on the hygroscopic layer 30, the hygroscopic layer 30 may undergo conversion at the time of contact of the two layers. Further, in some cases, bubbles or the like may be generated at the interface between the hygroscopic layer 30 and the gas releasing layer 41.

Therefore, in order to prevent direct contact between the hygroscopic layer 30 and the gas releasing layer 41, the gas permeable layer 42 is provided between the hygroscopic layer 30 and the gas releasing layer 41. A constituent material of the gas permeable layer 42 is not specifically limited insofar as the gas permeable layer 42 can prevent direct contact between the hygroscopic layer 30 and the gas releasing layer 41. However, the thickness of the gas permeable layer 42 is required to be set so that the gas permeable layer 42 is permeable to gas to the extent that gas evolved from the hygroscopic layer 30 can go through to the gas releasing layer 41. For example, when an inorganic material such as SiN, SiON, or SiO₂ or a porous material such as Al₂O₃ is used, the thickness of the gas permeable layer 42 is preferably 10 nm to 1,000 nm, and more preferably 50 nm to 500 nm.

When a constituent material of the gas permeable layer 42 is an inorganic material such as SiN, SiON, or SiO₂, the gas permeable layer 42 can be formed by a vacuum film forming method such as sputtering or CVD.

### Third Embodiment

FIG. 3 is a schematic cross-sectional view illustrating an organic EL display device according to a third embodiment of the present invention. In the following, the third embodiment according to the present invention is described with reference to FIG. 3. Note that, in the following description, points different from those in the first embodiment are mainly described.

An organic EL display device 3 illustrated in FIG. 3 is different from the organic EL display device in the first embodiment in that the gas releasing member 40 for releasing gas evolved from the hygroscopic layer 30 is provided not only over the hygroscopic layer 30 but also immediately below the hygroscopic layer 30. Specifically, in this embodiment, the gas releasing members 40 are provided so as to vertically sandwich the hygroscopic layer 30. The gas releasing members 40 which form the organic EL display device 3 illustrated in FIG. 3 are, specifically, a composite member including a first gas releasing layer 41a provided between the organic EL element 20 or the substrate 10 and the hygroscopic layer 30 and a second gas releasing layer 41b provided between the hygroscopic layer 30 and the sealing substrate 50. Note that, both the first gas releasing layer 41a and the second gas releasing layer 41b are held in contact with the hygroscopic layer 30. By increasing the number of the gas releasing layers as in this embodiment, the efficiency of releasing gas can be improved. Further, it is possible to inhibit stress caused by the contraction in volume of the hygroscopic layer due to the moisture absorption from transferring to the organic EL element.

In this embodiment, the gas releasing layers (41a and 41b) are formed of a resin material such as a UV-curable resin, a thermosetting resin, or a thermoplastic resin. Further, when a resin color filter or the like is required to be formed on the organic EL element 20, any one of the two kinds of gas releasing layers (41a and 41b) may function as the color filter. Note that, in this embodiment, when the first gas releasing layer 41a is provided, for the purpose of protecting the organic EL element 20, a protective layer (not shown) formed of an inorganic material such as SiN, SiON, or SiO₂ may be formed before the first gas releasing layer 41a is formed.

### Fourth Embodiment

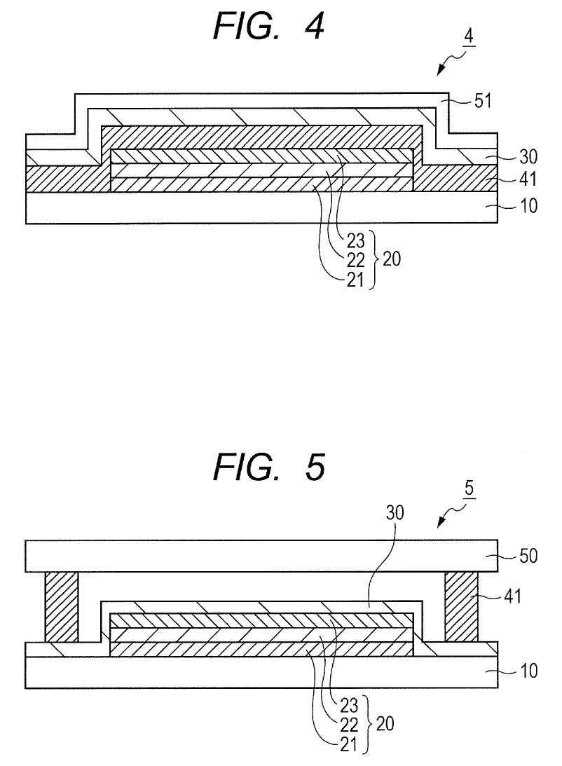

FIG. 4 is a schematic cross-sectional view illustrating an organic EL display device according to a fourth embodiment of the present invention. In the following, the fourth embodiment according to the present invention is described with reference to FIG. 4. Note that, in the following description, points different from those in the first embodiment are mainly described.

An organic EL display device 4 illustrated in FIG. 4 is different from the organic EL display device in the first embodiment in that the gas releasing member 41 for releasing gas evolved from the hygroscopic layer 30 is provided immediately below the hygroscopic layer 30. Note that, in the organic EL display device 4 illustrated in FIG. 4, the gas releasing layer 41 is provided in contact with the hygroscopic layer 30.

In this way, according to the present invention, insofar as the gas releasing member is provided in contact with the hygroscopic layer 30 and part thereof is exposed to the outside, the location thereof is not specifically limited. Note that, in this embodiment, when the gas releasing layer 41 is provided, for the purpose of protecting the organic EL element 20, a protective layer (not shown) formed of an inorganic material such as SiN, SiON, or SiO₂ may be formed before the gas releasing layer 41 is formed.

Further, in the organic EL display device 4 illustrated in FIG. 4, instead of the sealing substrate 50 illustrated in FIGS. 1 to 3, a sealing film 51 is provided on the hygroscopic layer 30 so as to be in direct contact with the hygroscopic layer 30, and the sealing film 51 seals the organic EL element 20.

Examples of a constituent material of the sealing film 51 include an inorganic material such as SiN, SiON, and SiO₂. When the sealing film 51 is formed of the above-mentioned inorganic material, the sealing film 51 is formed by a vacuum film forming method such as sputtering or CVD. Further, the thickness of the sealing film 51 is not specifically limited insofar as the sealing film 51 can prevent infiltration of moisture from the outside, but it is preferred that the thickness of the sealing film 51 be about 1 μm to 10 μm. Further, the sealing film 51 may be formed of a single layer or may have a laminated structure including multiple layers. Note that, when the sealing film 51 has a laminated structure, constituent materials of the respective layers may be of the same kind, or may be of different kinds.

By directly forming the sealing film 51 on the hygroscopic layer 30 as in this embodiment, an organic EL display device which is thin and has a high moisture resistant ability can be obtained.

### Fifth Embodiment

FIG. 5 is a schematic cross-sectional view illustrating an organic EL display device according to a fifth embodiment of the present invention. In the following, points different from those in the first embodiment are mainly described.

Differently from the first embodiment in which the gas releasing member fills the space between the sealing member and the hygroscopic layer, in an organic EL display device 5 illustrated in FIG. 5, the gas releasing layer 41 formed of a resin material having a bonding function is provided on the outer periphery of a display region so as to surround the display region, and the sealing substrate 50 is bonded to the substrate 10. The gas releasing layer 41 is provided so as to be in contact with the hygroscopic layer 30 and the sealing substrate 50 and so that part thereof is exposed to the outside. Specifically, the gas releasing layer 41 is provided so as to avoid a region over the organic EL element, and there is a sealed space between the sealing substrate 50 and the hygroscopic layer 30.

In the case of the organic EL display device 5 illustrated in FIG. 5, gas generated due to moisture absorption by the hygroscopic layer 30 formed on the organic EL element 20 is once released into the sealed space, and then is released via the gas releasing layer 41 to the outside. Therefore, the gas can be released only by passing through the gas releasing layer around the display region, and thus the gas can be released promptly.

### Example 1

In this example (Example 1), the organic EL display device illustrated in FIG. 1 was manufactured by the method described in the following.

(1) Step of Manufacturing Substrate with Electrode

After a pixel circuit including a low temperature polysilicon TFT was formed on a glass substrate, a semiconductor protective layer formed of SiN and a planarization film formed of a polyimide resin were formed in succession on the pixel circuit to manufacture the substrate 10. Then, a film of AlNd and a film of ITO were formed in this order on the substrate 10 by sputtering to form a laminated electrode film including the AlNd film and the ITO film. In this case, the thickness of the AlNd film was 100 nm while the thickness of the ITO film was 38 nm. Then, by patterning the laminated electrode film for each pixel, the first electrode 21 was formed. Then, a polyimide resin was spin coated on the substrate 10 and on the first electrode 21, and patterning was carried out by photolithography so that an opening (this opening corresponds to a pixel) was formed in a portion in which the first electrode 21 was formed, to thereby form a pixel separation layer (not shown). In this case, the pitch of the pixels was 30 μam and the shape of an exposed portion of the first electrode 21 by the opening was a 10-μm square. Then, the substrate 10 was ultrasonic cleaned with isopropyl alcohol (IPA), followed by boil cleaning and drying, and further UV/ozone cleaning. The substrate with an electrode obtained by the above-mentioned step was used in the following step.

(2) Step of Forming Organic Compound Layer

The organic compound layer 22 was formed on the first electrode 21 by vacuum deposition. The step is described specifically in the following.

First, a film of HT-1 (FL03) represented by the following formula was formed to form a hole transport layer. In this case, the thickness of the hole transport layer was 87 nm.

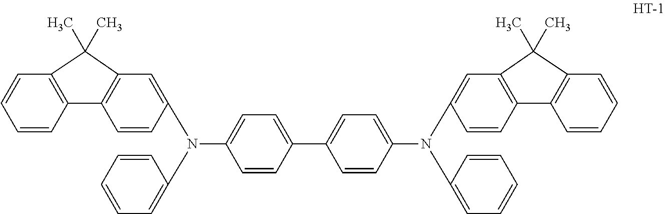 [SMILES: CC1(C)c2ccccc2-c2ccc(N(c3ccccc3)c3ccc(-c4ccc(N(c5ccccc5)c5ccc6c(c5)C(C)(C)c5ccccc5-6)cc4)cc3)cc21]

Then, a shadow mask having an opening in a region in which a red organic EL element was to be provided was used to codeposit CBP (carbazole compound, host) and Ir(piq)₃ (guest, the amount of the added guest was 9 wt % to the total weight of the host and the guest), to thereby form a red emission layer. In this case, the thickness of the red emission layer was 30 nm. Then, a shadow mask having an opening in a region in which a green organic EL element was to be provided was used to codeposit Alq₃ (aluminum chelate complex, host) and coumarin 6 (guest, the amount of the added guest was 1 wt % to the total weight of the host and the guest), to thereby form a green emission layer. In this case, the thickness of the green emission layer was 40 nm. Then, a shadow mask having an opening in a region in which a blue organic EL element was to be provided was used to codeposit BAlq (aluminum chelate complex, host) and perylene (guest, the amount of the added guest was 3 wt % to the total weight of the host and the guest), to thereby form a blue emission layer. In this case, the thickness of the blue emission layer was 25 nm.

Then, a film of Bphen as a phenanthroline compound was formed on the emission layer to form an electron transport layer. In this case, the thickness of the electron transport layer was 10 nm. Then, Bphen and cesium carbonate (Cs₂CO₃) were codeposited (The weight ratio between Bphen and Cs₂CO₃ was 90:10) on the electron transport layer to form an electron injection layer. In this case, the thickness of the electron injection layer was 40 nm. By the above-mentioned step, the organic compound layer 22 was formed.

(3) Step of Forming Second Electrode

Then, the substrate 10 on which the layers up to the organic compound layer 22 were formed was moved into a sputtering apparatus without breaking the vacuum, and after that, a film of Ag and a film of indium zinc oxide were formed in succession on the organic compound layer 22 by sputtering. In this way, a laminated electrode layer was formed in which an ultra-thin Ag film and a transparent electrode film were laminated in this order. In this case, the thickness of the ultra-thin Ag film was 10 nm while the thickness of the transparent electrode film was 50 nm. By the above-mentioned step, the organic EL element 20 was manufactured in which the first electrode 21, the organic compound layer 22, and the second electrode 23 were formed in this order on the substrate 10.

(4) Step of Forming Protective Layer

Then, without breaking the vacuum, a protective layer (not shown) formed of SiN was formed on the organic EL element 20 and on the substrate 10 by plasma CVD using SiH₄ gas, N₂ gas, and H₂ gas. In this case, the thickness of the protective layer was 0.5 μm.

(5) Step of Forming Hygroscopic Layer

Then, the substrate 10 on which the layers up to the protective layer were formed was moved into a glove box under the atmosphere of nitrogen. Then, an application liquid prepared by diluting polysilazane (manufactured by AZ Electronic Materials, AQUAMICA NAX120-20) five times with dibutyl ether was dropped on the protective layer and applied thereon by spin coating. Then, after the substrate 10 was transported into a vacuum drying oven, the inside of the vacuum drying oven was held at 60° C. and dibutyl ether was completely evaporated to form the hygroscopic layer 30. In this case, the thickness of the hygroscopic layer 30 was 130 nm.

(6) Step of Forming Gas Releasing Layer

Then, an acrylic thermosetting resin sheet at a thickness of 20 μm was bonded onto the sealing substrate 50. Note that, the acrylic thermosetting resin sheet not only functions as the gas releasing layer 41 but also, in the subsequent step, functions as an adhesive layer which bonds the substrate 10 and the sealing substrate 50 together.

(7) Sealing Step

Next, under vacuum, the sealing substrate 50 and the substrate 10 on which the layers up to the hygroscopic layer 30 were formed were bonded together so that the gas releasing layer 41 was held in contact with the hygroscopic layer 30 and part of the gas releasing layer 41 was exposed, and after that, prebaking was carried out at 80° C. Then, the bonded substrate was moved into a glove box, and heated and cured on a hot plate at 100° C., to thereby carry out sealing of the organic EL element 20. By the above-mentioned step, the organic EL display device 1 illustrated in FIG. 1 was obtained.

In the obtained organic EL display device, the gas releasing layer 41 was provided on the hygroscopic layer 30 so as to be in contact with the hygroscopic layer and so that part of the gas releasing layer 41 was exposed to the outside, and thus in a durability test carried out at a temperature of 85° C. and a humidity of 85%, neither evolution of air bubbles nor separation from the sealing substrate was observed after a lapse of 500 hours.

### Example 2

In this example (Example 2), the organic EL display device illustrated in FIG. 2 was manufactured by the method described in the following. Further, in the following description, points different from those in Example 1 are mainly described.

(1) Step of Manufacturing Substrate with Electrode

The substrate 10 with the first electrode 21 was manufactured by a method similar to that in Example 1.

(2) Step of Forming Organic Compound Layer

The organic compound layer 22 was formed by a method similar to that in Example 1.

(3) Step of Forming Second Electrode

The second electrode 23 was formed by a method similar to that in Example 1.

(4) Step of Forming Protective Layer

The protective layer (not shown) was formed by a method similar to that in Example 1.

(5) Step of Forming Hygroscopic Layer

The hygroscopic layer 30 was formed by a method similar to that in Example 1.

(6) Step of Forming Gas Releasing Member

Then, the substrate 10 on which the layers up to the hygroscopic layer 30 were formed was transported into a CVD chamber. After that, an SiN film was formed on the hygroscopic layer 30 by plasma CVD using SiH₄ gas, N₂ gas, and H₂ gas to form the gas permeable layer 42. In this case, the thickness of the gas permeable layer 42 was 0.2 μm.

Then, an epoxy-based thermosetting resin sheet at a thickness of 20 μm was bonded onto the sealing substrate 50. Note that, the epoxy-based thermosetting resin sheet not only functions as the gas releasing layer 41 but also, in the subsequent step, functions as an adhesive layer which bonds the substrate 10 and the sealing substrate 50 together.

(7) Sealing Step

Next, under vacuum, the sealing substrate 50 and the substrate 10 on which the layers up to the hygroscopic layer 30 were formed were bonded together so that the gas releasing layer 41 was held in contact with the gas permeable layer 42, and after that, prebaking was carried out at 80° C. Then, the bonded substrate was moved into a glove box, and heated and cured on a hot plate at 100° C., to thereby carry out sealing of the organic EL element 20. By the above-mentioned step, the organic EL display device was obtained. Note that, in this example, the hygroscopic layer 30 was held in contact with the gas releasing member 40 formed by laminating the gas permeable layer 42 and the gas releasing layer 41 in this order. By the above-mentioned step, the organic EL display device 2 illustrated in FIG. 2 was obtained.

In the obtained organic EL display device, the gas releasing member 40 was provided on the hygroscopic layer 30 so as to be in contact with the hygroscopic layer 30, and thus in a durability test carried out at a temperature of 85° C. and a humidity of 85%, neither evolution of air bubbles nor separation from the sealing substrate was observed after a lapse of 500 hours. Note that, in the organic EL display device 2 manufactured in this example, the gas permeable layer 42 was formed over the hygroscopic layer 30, and thus, the hygroscopic layer 30 and the epoxy resin film (gas releasing layer 41) are not in direct contact with each other. Therefore, evolution of minute air bubbles is inhibited, which is thought to be caused by reaction between a hydroxyl group contained in the epoxy resin skeleton and polysilazane.

### Example 3

In this example (Example 3), the organic EL display device illustrated in FIG. 3 was manufactured by the method described in the following. Further, in the following description, points different from those in Example 1 are mainly described.

(1) Step of Manufacturing Substrate with Electrode

The substrate 10 with the first electrode 21 was manufactured by a method similar to that in Example 1.

(2) Step of Forming Organic Compound Layer

The organic compound layer 22 was formed on the first electrode 21 by vacuum deposition. The step is described specifically in the following.

First, a film of HT-1 (FL03) represented by the following formula was formed to form a hole transport layer. In this case, the thickness of the hole transport layer was 87 nm.

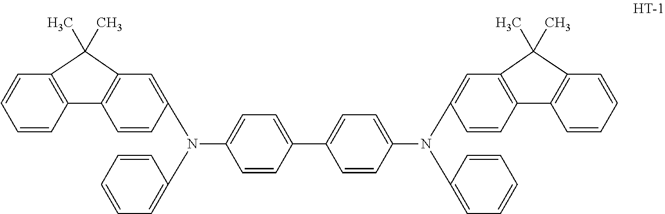 [SMILES: CC1(C)c2ccccc2-c2ccc(N(c3ccccc3)c3ccc(-c4ccc(N(c5ccccc5)c5ccc6c(c5)C(C)(C)c5ccccc5-6)cc4)cc3)cc21]

Then, CBP (carbazole compound, host) and Firpic (fluorinated Ir complex-based compound, guest, the amount of the added guest was 6 wt % to the total weight of the host and the guest) were codeposited on the hole transport layer to form a blue emission layer. In this case, the thickness of the blue emission layer was 20 nm. Then, CBP (carbazole compound, host) and Btp₂Ir (acac) (Ir complex-based compound, guest, the amount of the added guest was 8 wt % to the total weight of the host and the guest) were codeposited on the blue emission layer to form a red emission layer. In this case, the thickness of the red emission layer was 2 nm.

Then, a film of Bphen as a phenanthroline compound was formed on the red emission layer to form an electron transport layer. In this case, the thickness of the electron transport layer was 10 nm. Then, Bphen and cesium carbonate (Cs₂CO₃) were codeposited (The weight ratio between Bphen and Cs₂CO₃ was 90:10) on the electron transport layer to form an electron injection layer. In this case, the thickness of the electron injection layer was 40 nm. By the above-mentioned step, an organic compound layer 22 which emits white light was formed.

(3) Step of Forming Second Electrode

The second electrode 23 was formed by a method similar to that in Example 1. By the above-mentioned step, the organic EL element 20 was manufactured in which the first electrode 21, the organic compound layer 22 which emits white light, and the second electrode 23 were formed in this order on the substrate 10.

(4) Step of Forming Protective Layer (First Protective Layer)

A protective layer (not shown) was formed by a method similar to that in Example 1. Note that, the protective layer formed in this step functions as a first protective layer.

(5) Step of Forming First Gas Releasing Layer

Then, a color filter layer formed of an acrylic resin was formed on the protective layer. Note that, the color filter layer functions as the first gas releasing layer 41a.

(6) Step of Forming Hygroscopic Layer

Then, the substrate 10 on which the layers up to the first gas releasing layer 41 were formed was dried in a vacuum drying oven for 10 hours to carry out sufficient dehydration treatment. Then, the substrate 10 was moved into a glove box under the atmosphere of nitrogen. Then, by a method similar to that in Example 1, the hygroscopic layer 30 was formed on the first gas releasing layer 41. In this case, the thickness of the hygroscopic layer 30 was 400 nm.

(7) Step of Forming Protective Layer (Second Protective Layer)

Then, after the substrate 10 on which the layers up to the hygroscopic layer 30 were formed was transported into a CVD chamber, an SiN film was formed on the hygroscopic layer 30 by plasma CVD using SiH₄ gas, N₂ gas, and H₂ gas to form a protective layer (not shown). Note that, the protective layer formed in this step functions as a second protective layer. Further, the thickness of the second protective layer was 0.2 μm.

(8) Step of Forming Second Gas Releasing Layer

Then, an epoxy-based thermosetting resin sheet at a thickness of 20 μm was bonded onto the sealing substrate 50. Note that, the epoxy-based thermosetting resin sheet not only functions as the second gas releasing layer 41b but also, in the subsequent step, functions as an adhesive layer which bonds the substrate 10 and the sealing substrate 50 together.

(9) Sealing Step

Next, under vacuum, the sealing substrate 50 and the substrate 10 on which the layers up to the hygroscopic layer 30 were formed were bonded together so that the second gas releasing layer 41b was held in contact with the hygroscopic layer 30, and, after that, prebaking was carried out at 80° C. Then, the bonded substrate was moved into a glove box, and heated and cured on a hot plate at 100° C., to thereby carry out sealing of the organic EL element 20. By the above-mentioned step, the organic EL display device 3 illustrated in FIG. 3 was obtained.

In the obtained organic EL display device 3, the gas releasing layers (41a and 41b) were provided so as to sandwich the hygroscopic layer 30 and so as to be in contact with the hygroscopic layer 30. Therefore, in a durability test carried out at a temperature of 85° C. and a humidity of 85%, neither evolution of air bubbles nor separation from the sealing substrate was observed after a lapse of 500 hours.

### Example 4

In this example (Example 4), after four organic EL display devices were formed on one substrate, the substrate was divided to separate the organic EL display devices from one another to form the organic EL display device illustrated in FIG. 4. In the following, points different from those in Example 3 are mainly described.

(1) Step of Manufacturing Substrate with Electrode

The substrate 10 with the first electrodes 21 for four organic EL display devices was manufactured by a method similar to that in Example 3.

(2) Step of Forming Organic Compound Layer

The organic compound layer 22 was formed on the first electrodes 21 with the use of a mask having openings corresponding to the four organic EL display devices, by a method similar to that in Example 3.

(3) Step of Forming Second Electrode

The second electrode 23 was formed on the organic compound layer 22 with the use of a mask having openings corresponding to the four organic EL display devices, by a method similar to that in Example 3.

(4) Step of Forming Protective Layer

A protective layer (corresponding to the first protective layer in Example 3) was formed without particularly using a mask, by a method similar to that in Example 3.

(5) Step of Forming Gas Releasing Layer

The gas releasing layer 41 (corresponding to the first gas releasing layer 41a in Example 3) was formed by a method similar to that in Example 3. The gas releasing layer 41 was provided continuously across the four organic EL display devices.

(6) Step of Forming Hygroscopic Layer

The hygroscopic layer 30 was formed continuously across the four organic EL display devices by a method similar to that in Example 3.

(7) Step of Forming Sealing Film

Then, after the substrate 10 on which the layers up to the hygroscopic layer 30 were formed was transported into a CVD chamber, the sealing film 51 formed of SiN was formed by plasma CVD using SiH₄ gas, N₂ gas, and H₂ gas. In this case, the thickness of the sealing film 51 was 2 μm. After that, the substrate was divided to separate the organic EL display devices from one another to obtain the organic EL display device illustrated in FIG. 4.

In the obtained organic EL display device, the gas releasing layer 41 was provided so as to be in contact with a bottom surface of the hygroscopic layer 30 and so that the gas releasing layer 41 was exposed to the outside on cut surfaces. Therefore, in a durability test carried out at a temperature of 85° C. and a humidity of 85%, neither evolution of air bubbles nor separation from the sealing substrate was observed after a lapse of 500 hours.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2012-069385, filed Mar. 26, 2012, and Japanese Patent Application No. 2012-093478, filed Apr. 17, 2012 which are hereby incorporated by reference herein in their entirety.

What is claimed is:

1. An organic electroluminescence display device, comprising:
a substrate;
an organic electroluminescence element formed on the substrate;
a hygroscopic layer for covering the organic electroluminescence element;
a gas releasing member provided in contact with the hygroscopic layer; and
a sealing member provided over the hygroscopic layer,
wherein the hygroscopic layer is formed of a hygroscopic silicon-containing polymer, and
wherein the gas releasing member includes a gas releasing layer comprising a resin material, and a part of the gas releasing layer is exposed to outside.

2. The organic electroluminescence display device according to claim 1, wherein the hygroscopic silicon-containing polymer comprises polysilazane.

3. The organic electroluminescence display device according to claim 1, wherein the gas releasing layer comprises any one of a UV-curable resin, a thermosetting resin, and a thermoplastic resin.

4. The organic electroluminescence display device according to claim 1, wherein the gas releasing member is provided between the hygroscopic layer and the sealing member, and between the hygroscopic layer and the organic electroluminescence element.

5. The organic electroluminescence display device according to claim 1, wherein the gas releasing member comprises a layer comprising any one of SiN, SiON, SiO₂, and Al₂O₃ provided on the hygroscopic layer side of the gas releasing layer, the gas releasing layer being provided between the hygroscopic layer and the sealing member.

6. The organic electroluminescence display device according to claim 1, further comprising a protective layer comprising an inorganic material between the organic electroluminescence element and the hygroscopic layer.

7. The organic electroluminescence display device according to claim 6, wherein the protective layer comprises any one of SiN, SiON, SiO₂, and Al₂O₃ and has a thickness of 10 nm or more.

8. The organic electroluminescence display device according to claim 1,
wherein the gas releasing member fills a space between the hygroscopic layer and the sealing member.

9. The organic electroluminescence display device according to claim 1, wherein the sealing member comprises an inorganic film formed by a vacuum film forming method.

10. The organic electroluminescence display device according to claim 1,
wherein the gas releasing member is provided so as to surround a region in which the organic electroluminescence element is provided, and
wherein a space exists between the organic electroluminescence element and the sealing member.
